(19) United States
(12) Patent Application Publication
(10) Pub. No.: US 2024/0413821 A1
(43) Pub. Date: Dec. 12, 2024

(54) CIRCUIT AND SYSTEM FOR ACCELERATING RECOVERY OF INTEGRATED CIRCUIT AGING

(71) Applicant: Shanghai Jiao Tong University, Shanghai (CN)

(72) Inventor: Xinfei Guo, Shanghai (CN)

(21) Appl. No.: 18/648,441

(22) Filed: Apr. 28, 2024

(30) Foreign Application Priority Data
Jun. 9, 2023 (CN) 202310686635.0

(51) Int. Cl. H03K 17/687

(52) U.S. Cl. CPC H03K 17/6872

(57) ABSTRACT

This invention provides an electric circuit and system for accelerating the recovery of integrated circuit aging. It comprises an integrated circuit, including PMOS transistors P1, P2, P3, P4, NMOS transistors N1, N2, N3, and N4. It further includes a control signal, which is connected to the gate electrodes of PMOS transistors P1, P2, P3, P4, NMOS transistors N1, N2, N3, and N4. By switching the ON/OFF states of MOS transistors, the circuit regulates the operational status of the integrated circuit. This circuit proposed by the current invention can effectively accelerate the recovery from two types of aging mechanisms in integrated circuits, thereby alleviating the performance degradation of integrated circuits caused by aging in the workload circuits.

### CROSS-REFERENCE TO RELATED APPLICATIONS

This application claims priority of Chinese Patent Application No. 202310686635.0, filed on Jun. 9, 2023, the entire contents of which are incorporated herein by reference.

### TECHNICAL FIELD

The present invention relates to the field of aging recovery circuit technology. Specifically, it pertains to an electric circuit and system for accelerating the aging recovery of integrated circuits.

### BACKGROUND TECHNOLOGY

Integrated circuit aging is caused by various physical effects, with Bias Temperature Instability (NBTI) being the primary mechanism for transistor aging and Electromigration (EM) being the primary mechanism for interconnect aging, both of which exhibit reversibility as the core aging mechanisms.

Currently, circuit structures and control methods for mitigating integrated circuit aging primarily focus on alleviating individual aging phenomena, unable to simultaneously suppress multiple types of aging. Meanwhile, circuit structures and control methods for mitigating Bias Temperature Instability (BTI) aging mainly involve adjusting the input vector to change the gate-source voltage of transistors or adjusting the signal duty cycle but fail to maximize improvement in aging phenomena. Additionally, circuit structures and control methods for mitigating electromigration aging mainly involve increasing the width of interconnect lines, resulting in wasted wiring resources and increased area overhead.

The Chinese patent document with publication number CN114499488A provides an electric circuit structure and control method for alleviating the aging of integrated circuits. This scheme proposes to streamline the circuit structure and reduce the offset of transistor threshold voltage, effectively suppressing the impact of NBTI (Negative Bias Temperature Instability) on the aging of integrated circuits. However, this scheme primarily focuses on alleviating the NBTI effect and can only be applied to integrated circuits that need to be in standby mode, which may result in additional area overhead.

The United States patent document with application number U.S. Pat. No. 9,086,865B2 provides an electric circuit structure for accelerating the recovery of NBTI effects. This is achieved by interchanging the VDD and VSS terminals of the electric load circuit. However, this method primarily focuses on mitigating NBTI effects and requires the additional introduction of multiple transistors and logic units, such as multiplexers, leading to significant area overhead.

### Invention Content

The invention aims to address deficiencies in existing technologies by providing an electric circuit and system for accelerating the recovery of integrated circuit aging.

According to the present invention, an electric circuit for accelerating the recovery of integrated circuit aging is provided, comprising:

Integrated circuit. The integrated circuit comprises a sequentially connected VDD pin, VDD power delivery network, and electrical load circuit at the VDD terminal; a sequentially connected VCC pin, VCC power delivery network, and electrical load circuit at the VCC terminal.

It further comprises PMOS transistors P1, P2, P3, and P4, as well as NMOS transistors N1, N2, N3, and N4.

PMOS transistor P1 is respectively connected to the VDD pin and the VDD power delivery network. PMOS transistor P2 is respectively connected to the VDD port and the VSS power delivery network. PMOS transistor P3 is respectively connected to the VSS power delivery network and the VDD port of the electrical load circuit. PMOS transistor P4 is respectively connected to the VDD power delivery network and the VDD port of the electrical load circuit.

NMOS transistors N1 are respectively connected to the VSS pin and the VSS power delivery network. NMOS transistors N2 are respectively connected to the VSS pin and the VDD power delivery network. NMOS transistors N3 are respectively connected to the VDD power delivery network and electrical load circuit at the VSS terminal. NMOS transistors N4 are respectively connected to the VSS power delivery network and the electrical load circuit at the VSS terminal.

It further includes a control signal, which is connected to the gate electrodes of PMOS transistors P1, P2, P3, P4, NMOS transistors N1, N2, N3, and N4. By controlling the ON/OFF states of MOS transistors, the circuit regulates the operational status of the integrated circuit.

Preferably, the operational state of the integrated circuit comprises a normal operating state, wherein PMOS transistors P1 and P4, as well as NMOS transistors N1 and N4, are in an ON state, while PMOS transistors P2 and P3, along with NMOS transistors N2 and N3, are in an OFF state.

Preferably, the operational status of the integrated circuit includes an Electromigration (EM) accelerated recovery state, wherein PMOS transistors P2 and P3, as well as NMOS transistors N2 and N3, are in an ON state, while PMOS transistors P1 and P4, along with NMOS transistors N1 and N4, are in an OFF state.

Preferably, the operational state of the integrated circuit includes a Bias Temperature Instability (BTI) accelerated recovery state. In this state, PMOS transistors P1 and P3, as well as NMOS transistors N1 and N3, are in the ON state, while PMOS transistors P2 and P4, along with NMOS transistors N2 and N4, are in the OFF state.

Preferably, the drain of PMOS transistor P1 is connected to the VDD pin, and the source of PMOS transistor P1 is connected to the VDD power delivery network; the source of PMOS transistor P2 is connected to the VDD pin, and the drain of PMOS transistor P2 is connected to the VSS power delivery network; the source of PMOS transistor P3 is connected to the VDD pin of the electric load circuit, and the drain of PMOS transistor P3 is connected to the VSS power delivery network; the source of PMOS transistor P4 is connected to the VDD power delivery network, and the drain of PMOS transistor P4 is connected to the VDD port of the electric load circuit.

The drain of NMOS transistor N1 is connected to the VSS pin, and the source of NMOS transistor N1 is connected to the VSS power delivery network. The drain of NMOS transistor N2 is connected to the VDD power delivery network, and the source of NMOS transistor N2 is connected to the VSS pin. The drain of NMOS transistor N3 is connected to the VDD power delivery network, and the source of NMOS transistor N3 is connected to the VSS port of the electric load circuit. The source of NMOS transistor N4 is connected to the VSS power delivery network, and the drain of NMOS transistor N4 is connected to the VSS port of the electric load circuit.

The present invention provides a system for accelerating the recovery of integrated circuit aging, comprising the circuit for accelerating the recovery of integrated circuit aging as described above.

Compared with the prior art, the present invention has the following beneficial effects:

1. The present invention introduces an electric circuit that significantly extends the lifespan of integrated circuits by merely adding eight transistors onto the existing integrated circuit. This circuit facilitates accelerated recovery from both electromigration aging and negative temperature bias instability aging without adversely affecting the normal operation of the integrated circuit or significantly increasing its area overhead.

The present invention achieves rapid switching between three operating modes by employing a simple control method. During the accelerated recovery of electromigration aging, the load can operate normally. This effectively addresses the circuit downtime caused by aging recovery, thus suppressing the impact of aging on integrated circuits and reducing production costs as well as power consumption costs.

Other beneficial effects of the present invention will be elucidated in specific embodiments by introducing technical features and solutions. It is expected that those skilled in the field will be able to comprehend the beneficial technical effects brought about by these technical features and solutions through these detailed descriptions.

### DESCRIPTION OF THE DRAWINGS

The other features, objects, and advantages of the present invention will become more apparent from the following detailed description of non-limiting embodiments with reference to the accompanying drawings:

FIG. 1 illustrates a schematic diagram of the circuit structure for accelerating the recovery of integrated circuit aging in the present invention.

FIG. 2 shows the truth table of the transistors corresponding to various states of the circuit for accelerating the recovery of integrated circuit aging in the present invention.

### SPECIFIC EMBODIMENTS

The following detailed description of the invention is provided in conjunction with specific embodiments. These embodiments will aid those skilled in the field in further understanding the present invention but do not limit the invention in any way. It should be noted that those skilled in the field can make various modifications and improvements without departing from the concept of the present invention. All such modifications and improvements are within the scope of the present invention.

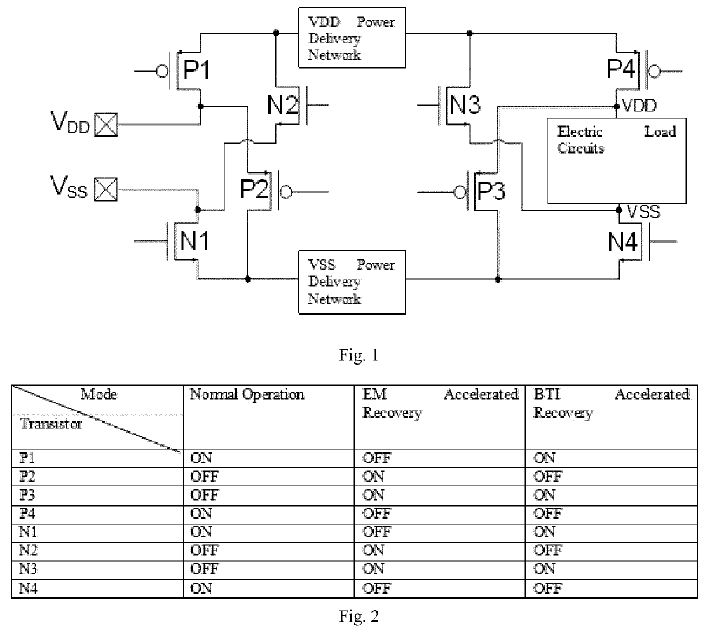

The present invention provides an electric circuit for accelerating the recovery of integrated circuit aging, as shown in FIG. 1, comprising:

Integrated circuit, wherein the integrated circuit comprises sequentially connected VDD pin, VDD power supply transmission network, and load circuit at the VDD terminal; sequentially connected VCC pin, VCC power supply transmission network, and electrical load circuit at the VCC terminal.

It further comprises eight transistors, including four P-type transistors and four N-type transistors, designated as PMOS transistors P1, P2, P3, P4, and NMOS transistors N1, N2, N3, and N4, respectively.

PMOS transistors P1 are respectively connected to the VDD pin and the VDD power delivery network. PMOS transistors P2 are respectively connected to the VDD port and the VSS power delivery network. PMOS transistors P3 are respectively connected to the VSS power delivery network and the VDD port of the electric load circuit. PMOS transistors P4 are respectively connected to the VDD power supply transmission network and the VDD port of the electric load circuit.

NMOS transistors N1 are respectively connected to the VSS pin and the VSS power delivery network, NMOS transistors N2 are respectively connected to the VSS pin and the VDD power delivery network, NMOS transistors N3 are respectively connected to the VDD power delivery network and the VSS terminal of the electric load circuit, and NMOS transistors N4 are respectively connected to the VSS power delivery network and the VSS terminal of the electric load circuit.

It further includes a control signal, which is connected to the gate electrodes of PMOS transistors P1, P2, P3, P4, NMOS transistors N1, N2, N3, and N4. By controlling the ON/OFF states of MOS transistors, the circuit regulates the operational status of the integrated circuit.

An electric circuit for accelerating the recovery of integrated circuit aging, as described in claim 1, is characterized in that the drain of PMOS transistor P1 is connected to the VDD pin, and the source of PMOS transistor P1 is connected to the VDD power delivery network; the source of PMOS transistor P2 is connected to the VDD pin, and the drain of PMOS transistor P2 is connected to the VSS power delivery network; the source of PMOS transistor P3 is connected to the VDD pin of the electric load circuit, and the drain of PMOS transistor P3 is connected to the VSS power delivery network; the source of PMOS transistor P4 is connected to the VDD power delivery network, and the drain of PMOS transistor P4 is connected to the VDD port of the electric load circuit.

The drain of NMOS transistor N1 is connected to the VSS pin, and the source of NMOS transistor N1 is connected to the VSS power delivery network. The drain of NMOS transistor N2 is connected to the VDD power delivery network, and the source of NMOS transistor N2 is connected to the VSS pin. The drain of NMOS transistor N3 is connected to the VDD power delivery network, and the source of NMOS transistor N3 is connected to the VSS port of the electric load circuit. The source of NMOS transistor N4 is connected to the VSS power delivery network, and the drain of NMOS transistor N4 is connected to the VSS port of the electric load circuit.

Referring to FIG. 2, this circuit operates in three modes as follows:

Operation Mode One: Normal operation. In this state, PMOS transistors P1 and P4, as well as NMOS transistors N1 and N4, are in an ON state, while PMOS transistors P2 and P3, along with NMOS transistors N2 and N3, are in an OFF state. In this state, the electric load circuit is under normal power supply conditions, and the entire circuit operates normally.

Operation Mode Two: EM acceleration recovery state. In this state, PMOS transistors P2 and P3, as well as NMOS transistors N2 and N3, are in the ON state, while PMOS transistors P1 and P4, along with NMOS transistors N1 and N4, are in the OFF state. The electric load circuit is under normal power supply, with the current direction through the VDD power delivery network and the VSS power delivery network reversed, entering the electromigration accelerated recovery state.

Operation Mode Three: BTI accelerated recovery state. In this state, PMOS transistors P1 and P3, as well as NMOS transistors N1 and N3, are in the ON state, while PMOS transistors P2 and P4, along with NMOS transistors N2 and N4, are in the OFF state. In this state, the electric load circuit is in the OFF state, entering the accelerated recovery state for Bias Temperature Instability (BTI) aging.

The present invention also provides a system for accelerating the recovery of integrated circuit aging, comprising the circuit for accelerating the recovery of integrated circuit aging as described above.

The specific embodiments of the present invention have been described above. It should be understood that the present invention is not limited to the particular embodiments described above. Those skilled in the art can make various changes or modifications within the scope of the claims without departing from the essence of the present invention. Embodiments and features in the present application can be combined with each other in any manner as long as they do not conflict.

1. A system for accelerating recovery of integrated circuit aging, comprising an electric circuit for accelerating recovery of integrated circuit aging, wherein
the electric circuit for accelerating recovery of integrated circuit aging comprises:
an integrated circuit, wherein
the integrated circuit comprises a VDD pin, a VDD power delivery network, and a VDD terminal for an electrical load circuit which are sequentially connected and a VCC pin, a VSS power delivery network, and a VSS terminal for the electrical load circuit which are sequentially connected;
a PMOS transistor P1, a PMOS transistor P2, a PMOS transistor P3, a PMOS transistor P4, an NMOS transistor N1, an NMOS transistor N2, an NMOS transistor N3, and an NMOS transistor N4, wherein
the PMOS transistor P1 is connected to the VDD pin and the VDD power delivery network; the PMOS transistor P2 is connected to the VDD pin and the VSS power delivery network; the PMOS transistor P3 is connected to the VSS power delivery network and the VDD terminal; and the PMOS transistor P4 is connected to the VDD power delivery network and the VDD terminal; and
the NMOS transistor N1 is connected to the VSS pin and the VSS power delivery network; the NMOS transistor N2 is connected to the VSS pin and the VDD power delivery network; the NMOS transistor N3 is connected to the VDD power delivery network and the VSS terminal; and the NMOS transistor N4 is connected to the VSS power delivery network and the VSS terminal; and
control terminals, wherein
the control terminals are connected to gate electrodes of the PMOS transistor P1, the PMOS transistor P2, the PMOS transistor P3, the PMOS transistor P4, the NMOS transistor N1, the NMOS transistor N2, the NMOS transistor N3, and the NMOS transistor N4; and by switching ON/OFF states of the PMOS transistor P1, the PMOS transistor P2, the PMOS transistor P3, the PMOS transistor P4, the NMOS transistor N1, the NMOS transistor N2, the NMOS transistor N3, and the NMOS transistor N4, switching is performed between operational states of an integrated circuit,
wherein a drain of the PMOS transistor P1 is connected to the VDD pin, and a source of the PMOS transistor P1 is connected to the VDD power delivery network; a source of the PMOS transistor P2 is connected to the VDD pin, and a drain of the PMOS transistor P2 is connected to the VSS power delivery network; a source of the PMOS transistor P3 is connected to the VDD terminal, and a drain of the PMOS transistor P3 is connected to the VSS power delivery network; and a source of the PMOS transistor P4 is connected to the VDD power delivery network, and a drain of the PMOS transistor P4 is connected to the VDD terminal,
wherein a drain of the NMOS transistor N1 is connected to the VSS pin, and a source of the NMOS transistor N1 is connected to the VSS power delivery network; a drain of the NMOS transistor N2 is connected to the VDD power delivery network, and a source of the NMOS transistor N2 is connected to the VSS pin; a drain of the NMOS transistor N3 is connected to the VDD power delivery network, and a source of the NMOS transistor N3 is connected to the VSS terminal; and a source of the NMOS transistor N4 is connected to the VSS power delivery network, and a drain of the NMOS transistor N4 is connected to the VSS terminal.

2. The system for accelerating recovery of integrated circuit aging according to claim 1, wherein the operational states of the integrated circuit include in a normal operating state, wherein the PMOS transistor P1, the PMOS transistor P4, the NMOS transistor N1 and the NMOS transistor N4 are in an ON state, while the PMOS transistor P2 the PMOS transistor P3, the NMOS transistor N2 and the NMOS transistor N3 are in an OFF state.

3. The system for accelerating recovery of integrated circuit aging according to claim 1, wherein the operational states of the integrated circuit include an EM acceleration recovery state; and in the EM acceleration recovery state, the PMOS transistor P2, the PMOS transistor P3, the NMOS transistor N2 and the NMOS transistor N3 are in an ON state, while the PMOS transistor P1, the PMOS transistor P4, the NMOS transistor N1 and the NMOS transistor N4 are in an OFF state.

4. The system for accelerating recovery of integrated circuit aging according to claim 1, wherein the operational states of the integrated circuit include a BTI accelerated recovery state; and in the BTI accelerated recovery state, the PMOS transistor P1, the PMOS transistor P3, the NMOS transistor N1 and the NMOS transistor N3 are in an ON state, while the PMOS transistor P2, the PMOS transistor P4, the NMOS transistor N2 and the NMOS transistor N4, are in an OFF state.

5.-7. (canceled)
